(19) United States
(12) Patent Application Publication
(10) Pub. No.: US 2025/0072491 A1
(43) Pub. Date: Mar. 6, 2025

(54) AEROSOL GENERATING DEVICE WITH FULL BRIDGE DRIVING CIRCUIT

(71) Applicant: KT&G CORPORATION, Daejeon (KR)

(72) Inventors: Jangwon SEO, Daejeon (KR); Gyung Min GO, Daejeon (KR); Chul Ho JANG, Bucheon-si (KR); Jin Chul JUNG, Daejeon (KR)

(73) Assignee: KT&G CORPORATION, Daejeon (KR)

(21) Appl. No.: 18/576,456

(22) PCT Filed: May 22, 2023
(86) PCT No.: PCT/KR2023/006883

§ 371 Date: Jan. 4, 2024

(30) Foreign Application Priority Data
May 23, 2022 (KR) 10-2022-0062616
Aug. 11, 2022 (KR) 10-2022-0100725

(51) Int. Cl. A24F 40/05; A24F 40/40; A24F 40/50; B06B 1/02; H03K 17/687

(52) U.S. Cl. CPC A24F 40/05; A24F 40/40; A24F 40/50; H03K 17/6871; B06B 1/02

(57) ABSTRACT

A driving circuit according to an example has a form of a full bridge including four switches, and the driving circuit includes a first alternating current power supply that provides a voltage to a gate terminal of a first switch and a gate terminal of a fourth switch, a second alternating current power supply that provides a voltage to a gate terminal of a second switch and a gate terminal of a third switch, and a direct current power supply that provides a direct current voltage to a drain terminal of the first switch and a drain terminal of the third switch.

### TECHNICAL FIELD

The following embodiments relate to a device for generating an aerosol, and more particularly, to a full bridge driving circuit of an aerosol generating device.

### BACKGROUND ART

These days, there is a gradual rise in the demand for electronic cigarettes. The rising demand for electronic cigarettes has accelerated the continued development of electronic cigarette-related functions. The electronic cigarette-related functions may include, in particular, functions according to types and characteristics of electronic cigarettes.

### DISCLOSURE OF THE INVENTION

### Technical Goals

An embodiment may provide a driving circuit for driving a vibrator of an aerosol generating device.

An embodiment may provide an aerosol generating device for generating an aerosol.

### Technical Solutions

According to an embodiment, a driving circuit may include, for supplying power to a vibrator of a cartridge, a first electrical contact connectable to a first end of the vibrator and a second electrical contact connectable to a second end of the vibrator, an inductor connected to the first electrical contact, wherein a first end of the inductor is connected to the first electrical contact, a first switch having a source terminal connected to a second end of the inductor, a second switch having a drain terminal connected to the second end of the inductor, wherein a source terminal of the second switch is connected to a ground, a third switch having a source terminal connected to the second electrical contact, a fourth switch having a drain terminal connected to the second electrical contact, wherein a source terminal of the fourth switch is connected to a ground, a first power supply configured to provide a voltage to a drain terminal of the first switch and a drain terminal of the third switch, a second power supply configured to provide a voltage to a gate terminal of the first switch and a gate terminal of the fourth switch, and a third power supply configured to provide a gate terminal of the second switch and a gate terminal of the third switch.

The first power supply may be configured to provide a direct current voltage to a drain terminal of the first switch and a drain terminal of the third switch.

A direct current voltage provided by the first power supply may be less than or equal to 15 volts (V).

The second power supply may be configured to provide a first alternating current voltage to the gate terminal of the first switch and the gate terminal of the fourth switch, and the third power supply may be configured to provide a second alternating current voltage to the gate terminal of the second switch and the gate terminal of the third switch.

A peak value of the first alternating current voltage and a peak value of the second alternating current voltage may each be less than or equal to 4 V.

The second power supply and the third power supply may operate alternately.

A voltage between the first end and the second end of the vibrator may be greater than or equal to 100 V.

The driving circuit may further include a fifth switch connected to the second electrical contact and a sixth switch positioned between the drain terminal of the third switch and the first power supply, wherein a source terminal of the sixth switch is connected to the drain terminal of the third switch, and a drain terminal of the sixth switch is connected to the first power supply, and wherein a first control signal provided to a gate terminal of the fifth switch and a second control signal provided to a gate terminal of the sixth switch may be different from each other.

A voltage between the first end and the second end of the vibrator may be greater than or equal to 50 V.

The driving circuit may be included in an electronic cigarette.

According to an embodiment, an electronic device may include a cartridge unit including a vibrator configured to generate an aerosol by vibrating an aerosol generating material and a body connected to the cartridge unit, wherein the body may include, when the cartridge unit is connected to the body, a driving circuit configured to operate the vibrator and a controller configured to control an operation of the driving circuit, and wherein the driving circuit may include, for supplying power to the vibrator of the cartridge unit, a first electrical contact connectable to a first end of the vibrator and a second electrical contact connectable to a second end of the vibrator, an inductor connected to the first electrical contact, wherein a first end of the inductor is connected to the first electrical contact, a first switch having a source terminal connected to a second end of the inductor, a second switch having a drain terminal connected to the second end of the inductor, wherein a source terminal of the second switch is connected to a ground, a third switch having a source terminal connected to the second electrical contact, a fourth switch having a drain terminal connected to the second electrical contact, wherein the source terminal of the second switch is connected to a ground, a first power supply configured to provide a voltage to a drain terminal of the first switch and a drain terminal of the third switch, a second power supply configured to provide a voltage to a gate terminal of the first switch and a gate terminal of the fourth switch, and a third power supply configured to provide a gate terminal of the second switch and a gate terminal of the third switch.

### Effects

A driving circuit for driving a vibrator of an aerosol generating device may be provided.

An aerosol generating device for generating an aerosol may be provided.

### BRIEF DESCRIPTION OF DRAWINGS

FIG. 1 is a block diagram of an aerosol generating device according to an embodiment.

FIG. 2 is a cross-sectional view of an aerosol generating device according to an embodiment.

FIG. 3 is a cross-sectional view of an aerosol generating module according to an example.

FIG. 4 is a schematic view of a cartridge according to an example.

FIG. 5 illustrates a driving circuit according to an embodiment.

FIG. 6 illustrates a voltage applied to a vibrator through a driving circuit according to an example.

FIG. 7 illustrates a driving circuit for switching between a full bridge mode and a half bridge mode according to an example.

FIG. 8 illustrates an equivalent circuit of a driving circuit that operates in a half bridge mode according to an example.

### BEST MODE FOR CARRYING OUT THE INVENTION

The following structural or functional description of embodiments is provided as an example only and various alterations and modifications may be made to the embodiments. Accordingly, the embodiments are not construed as limited to the disclosure and should be understood to include all changes, equivalents, or replacements within the idea and the technical scope of the disclosure.

Although terms, such as first, second, and the like, are used to describe various components, the components are not limited to the terms. These terms should be used only to distinguish one component from another component. For example, a first component may be referred to as a second component, and similarly the second component may be referred to as the first component.

It should be understood that if it is described that one component is “connected,” “coupled,” or “joined” to another component, a third component may be “connected,” “coupled,” and “joined” between the first and second components, although the first component may be directly connected, coupled, or joined to the second component.

The singular forms “a,” “an,” and “the” include the plural forms as well, unless the context clearly indicates otherwise. It will be further understood that the terms “comprises/comprising” or “includes/including” when used herein, specify the presence of stated features, integers, steps, operations, elements, components or combinations thereof, but do not preclude the presence or addition of one or more other features, integers, steps, operations, elements, components or combinations thereof.

Unless otherwise defined, all terms used herein including technical or scientific terms have the same meaning as those generally understood by one of ordinary skill in the art to which this disclosure pertains. Terms, such as those defined in commonly used dictionaries, should be interpreted to have meanings matching with contextual meanings in the relevant art, and are not to be interpreted to have an ideal or excessively formal meaning unless otherwise defined herein.

Hereinafter, embodiments will be described in detail with reference to the accompanying drawings. When describing the embodiments with reference to the accompanying drawings, like reference numerals refer to like elements and a repeated description related thereto will be omitted.

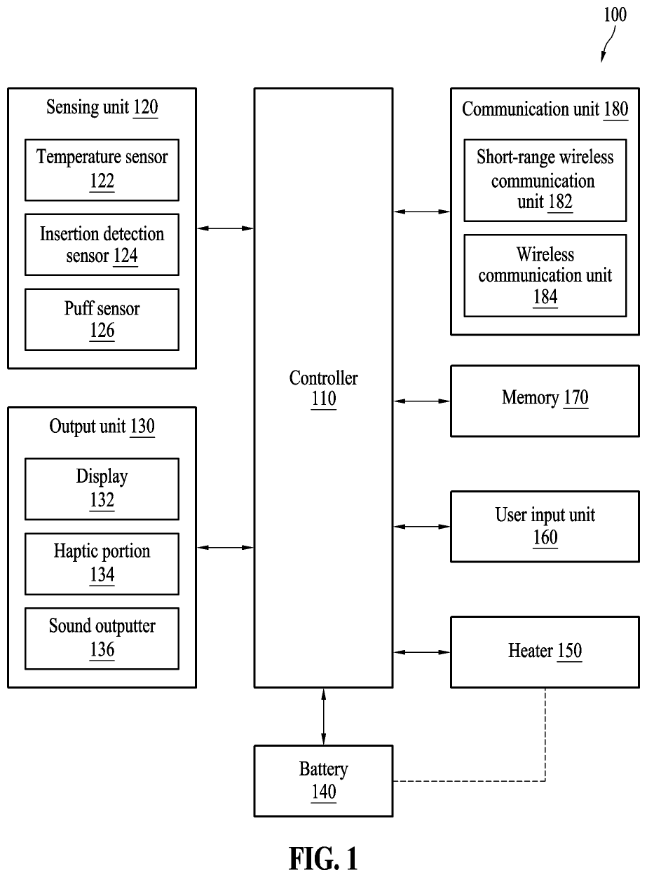

FIG. 1 is a block diagram of an aerosol generating device according to an embodiment.

According to an embodiment, an aerosol generating device 100 of FIG. 1 may include a controller 110, a sensing unit 120, an output unit 130, a battery 140, a heater 150, a user input unit 160, a memory 170, and a communication unit 180. However, an internal structure of the aerosol generating device 100 is not limited to what is shown in FIG. 1. It is to be understood by one of ordinary skill in the art to which the disclosure pertains that some of the components shown in FIG. 1 may be omitted or new components may be added according to the design of the aerosol generating device 100.

The sensing unit 120 may sense a state of the aerosol generating device 100 or a state of an environment around the aerosol generating device 100, and transmit sensing information obtained through the sensing to the controller 110. Based on the sensing information, the controller 110 may control the aerosol generating device 100 to control operations of the heater 150, restrict smoking, determine whether an aerosol generating article (e.g., an aerosol generating article, a cartridge, etc.) is inserted, display a notification, and perform other functions.

The sensing unit 120 may include at least one of a temperature sensor 122, an insertion detection sensor 124, or a puff sensor 126. However, embodiments are not limited thereto.

The temperature sensor 122 may sense a temperature at which the heater 150 (or an aerosol generating material) is heated. The aerosol generating device 100 may include a separate temperature sensor for sensing a temperature of the heater 150, or the heater 150 itself may perform a function as a temperature sensor. Alternatively, the temperature sensor 122 may be arranged around the battery 140 to monitor a temperature of the battery 140.

The insertion detection sensor 124 may sense whether the aerosol generating article is inserted and/or removed. The insertion detection sensor 124 may include, for example, at least one of a film sensor, a pressure sensor, a light sensor, a resistive sensor, a capacitive sensor, an inductive sensor, or an infrared sensor, which may sense a signal change by the insertion and/or removal of the aerosol generating article.

The puff sensor 126 may sense a puff from a user based on various physical changes in an airflow path or airflow channel. For example, the puff sensor 126 may sense the puff from the user based on any one of a temperature change, a flow change, a voltage change, and a pressure change.

The sensing unit 120 may further include at least one of a temperature/humidity sensor, an atmospheric pressure sensor, a magnetic sensor, an acceleration sensor, a gyroscope sensor, a position sensor (e.g., a global positioning system (GPS)), a proximity sensor, or a red, green, blue (RGB) sensor (e.g., an illuminance sensor), in addition to the sensors 122 to 126 described above. A function of each sensor may be intuitively inferable from its name by one of ordinary skill in the art, and thus, a more detailed description thereof will be omitted here.

The output unit 130 may output information about the state of the aerosol generating device 100 and provide the information to the user. The output unit 130 may include at least one of a display 132, a haptic portion 134, or a sound outputter 136. However, embodiments are not limited thereto. When the display 132 and a touchpad are provided in a layered structure to form a touchscreen, the display 132 may be used as an input device in addition to an output device.

The display 132 may visually provide the information about the aerosol generating device 100 to the user. The information about the aerosol generating device 100 may include, for example, a charging/discharging state of the battery 140 of the aerosol generating device 100, a preheating state of the heater 150, an insertion/removal state of the aerosol generating article, a limited usage state (e.g., an abnormal article detected) of the aerosol generating device 100, or the like, and the display 132 may externally output the information. The display 132 may be, for example, a liquid-crystal display panel (LCD), an organic light-emitting display panel (OLED), or the like. The display 132 may also be in the form of a light-emitting diode (LED) device.

The haptic portion 134 may provide the information about the aerosol generating device 100 to the user in a haptic way by converting an electrical signal into a mechanical stimulus or an electrical stimulus. The haptic portion 134 may include, for example, a motor, a piezoelectric element, or an electrical stimulation device.

The sound outputter 136 may provide the information about the aerosol generating device 100 to the user in an auditory way. For example, the sound outputter 136 may convert an electrical signal into a sound signal and externally output the sound signal.

The battery 140 may supply power to be used to operate the aerosol generating device 100. The battery 140 may supply power to heat the heater 150. In addition, the battery 140 may supply power required for operations of the other components (e.g., the sensing unit 120, the output unit 130, the user input unit 160, the memory 170, and the communication unit 180) included in the aerosol generating device 100. The battery 140 may be a rechargeable battery or a disposable battery. The battery 140 may be, for example, a lithium polymer (LiPoly) battery. However, embodiments are not limited thereto.

The heater 150 may receive power from the battery 140 to heat the aerosol generating material. Although not shown in FIG. 1, the aerosol generating device 100 may further include a power conversion circuit (e.g., a direct current (DC)-to-DC (DC/DC) converter) that converts power of the battery 140 and supplies the power to the heater 150. In addition, when the aerosol generating device 100 generates an aerosol in an induction heating manner, the aerosol generating device 100 may further include a DC-to-alternating current (AC) (DC/AC) converter that converts DC power of the battery 140 into AC power.

The controller 110, the sensing unit 120, the output unit 130, the user input unit 160, the memory 170, and the communication unit 180 may receive power from the battery 140 to perform functions. Although not shown in FIG. 1, the aerosol generating device 100 may further include a power conversion circuit, for example, a low dropout (LDO) circuit or a voltage regulator circuit, which converts power of the battery 140 and supplies the power to respective components.

In an embodiment, the heater 150 may be formed of a predetermined electrically resistive material that is suitable. For example, the electrically resistive material may be a metal or a metal alloy including, for example, titanium, zirconium, tantalum, platinum, nickel, cobalt, chromium, hafnium, niobium, molybdenum, tungsten, tin, gallium, manganese, iron, copper, stainless steel, nichrome, or the like. However, embodiments are not limited thereto. In addition, the heater 150 may be implemented as a metal heating wire, a metal heating plate on which an electrically conductive track is arranged, a ceramic heating element, or the like, but is not limited thereto.

According to an embodiment, the heater 150 may be an induction heater. For example, the heater 150 may include a susceptor that heats the aerosol generating material by generating heat through a magnetic field applied by a coil.

In an embodiment, the heater 150 may be a vibrator that provides an ultrasonic vibration to the aerosol generating material. For example, when the vibrator vibrates the aerosol generating material with ultrasonic waves, the aerosol generating material may be aerosolized.

In an embodiment, the heater 150 may include a plurality of heaters. For example, the heater 150 may include a first heater for heating the aerosol generating article and a second heater for heating a liquid.

The user input unit 160 may receive information input from the user or may output information to the user. For example, the user input unit 160 may include a keypad, a dome switch, a touchpad (e.g., a contact capacitive type, a pressure resistive film type, an infrared sensing type, a surface ultrasonic conduction type, an integral tension measurement type, a piezo effect method, etc.), a jog wheel, a jog switch, or the like. However, embodiments are not limited thereto. In addition, although not shown in FIG. 1, the aerosol generating device 100 may further include a connection interface such as a universal serial bus (USB) interface, and may be connected to another external device through the connection interface such as a USB interface to transmit and receive information or to charge the battery 140.

The memory 170, which is hardware for storing various pieces of data processed in the aerosol generating device 100, may store data processed by the controller 110 and data to be processed by the controller 110. The memory 170 may include at least one type of storage medium of a flash memory type memory, a hard disk type memory, a multimedia card micro type memory, a card type memory (e.g., an SD or XD memory), a random access memory (RAM), a static random access memory (SRAM), a read-only memory (ROM), an electrically erasable programmable read-only memory (EEPROM), a programmable read-only memory (PROM), a magnetic memory, a magnetic disk, or an optical disk. The memory 170 may store an operating time of the aerosol generating device 100, a maximum number of puffs, a current number of puffs, at least one temperature profile, data associated with a smoking pattern of the user, or the like.

The communication unit 180 may include at least one component for communicating with another electronic device. For example, the communication unit 180 may include a short-range wireless communication unit 182 and a wireless communication unit 184.

The short-range wireless communication unit 182 may include a Bluetooth communication unit, a Bluetooth low energy (BLE) communication unit, a near field communication unit, a wireless area network (WLAN) (wireless fidelity (Wi-Fi)) communication unit, a ZigBee communication unit, an infrared data association (IrDA) communication unit, a Wi-Fi direct (WFD) communication unit, an ultra-wideband (UWB) communication unit, and an Ant+ communication unit. However, embodiments are not limited thereto.

The wireless communication unit 184 may include, for example, a cellular network communication unit, an Internet communication unit, a computer network (e.g., a local area network (LAN) or a wide-area network (WAN)) communication unit, or the like. However, embodiments are not limited thereto. The wireless communication unit 184 may use subscriber information (e.g., international mobile subscriber identity (IMSI)) to identify and authenticate the aerosol generating device 100 in a communication network.

The controller 110 may control the overall operation of the aerosol generating device 100. In an embodiment, the controller 110 may include at least one processor. The processor may be implemented as an array of a plurality of logic gates, or may be implemented as a combination of a general-purpose microprocessor and a memory in which a program executable by the microprocessor is stored. In addition, it is to be understood by one of ordinary skill in the art to which the disclosure pertains that the processor may be implemented in other types of hardware.

The controller 110 may control the temperature of the heater 150 by controlling supply of power from the battery 140 to the heater 150. For example, the controller 110 may control the supply of power by controlling switching of a switching element between the battery 140 and the heater 150. As another example, a direct heating circuit may control the supply of power to the heater 150 according to a control command from the controller 110.

The controller 110 may analyze a sensing result obtained by the sensing of the sensing unit 120 and control processes to be performed thereafter. For example, the controller 110 may control power to be supplied to the heater 150 to start or end an operation of the heater 150 based on the sensing result obtained by the sensing unit 120. As another example, the controller 110 may control an amount of power to be supplied to the heater 150 and a time for which the power is to be supplied, such that the heater 150 may be heated up to a predetermined temperature or maintained at a desired temperature, based on the sensing result obtained by the sensing unit 120.

The controller 110 may control the output unit 130 based on the sensing result obtained by the sensing unit 120. For example, when a number of puffs counted through the puff sensor 126 reaches a preset number, the controller 110 may inform the user that the aerosol generating device 100 is to be ended soon, through at least one of the display 132, the haptic portion 134, or the sound outputter 136.

In an embodiment, the controller 110 may control a power supply time and/or a power supply amount for the heater 150 according to a state of the aerosol generating article sensed by the sensing unit 120. For example, when the aerosol generating article is in an over-humidified state, the controller 110 may control the power supply time for an inductive coil to increase a preheating time, compared to a case where the aerosol generating article is in a general state.

An embodiment may also be implemented in the form of a recording medium including instructions executable by a computer, such as a program module executable by the computer. A computer-readable medium may be any available medium that may be accessed by a computer and includes a volatile medium, a non-volatile medium, a removable medium, and a non-removable medium. In addition, the computer-readable medium may include both a computer storage medium and a communication medium. The computer storage medium includes all of a volatile medium, a non-volatile medium, a removable medium, and a non-removable medium implemented by any method or technology for storage of information such as computer-readable instructions, data structures, program modules or other data. The communication medium typically includes computer-readable instructions, data structures, other data in modulated data signals such as program modules, or other transmission mechanisms, and includes any information transfer medium.

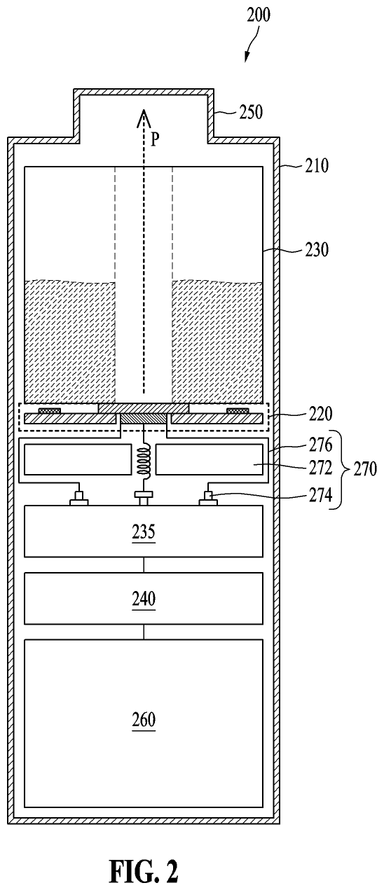

FIG. 2 is a cross-sectional view of an aerosol generating device according to an embodiment.

According to an embodiment, an aerosol generating device 200 (e.g., the aerosol generating device 100 of FIG. 1) may include a housing 210, an aerosol generating module 220, a cartridge 230, a driving circuit 235, a controller 240, a mouthpiece 250, a battery 260, and an auxiliary elements 270.

In an embodiment, the housing 210 may be configured to accommodate various electronic/mechanical components. For example, the aerosol generating module 220, the cartridge 230, the driving circuit 235, the controller 240, the battery 260, and the auxiliary elements 270 may all be accommodated in the housing 210 and safely protected from an external stimulus (e.g., dust, impact, heat, etc.). As another example, the aerosol generating device 200 may include a cartridge unit including the aerosol generating module 220 and the cartridge 230 and a body including the driving circuit 235, the controller 240, and the battery 260. The auxiliary elements 270 may be included in either the cartridge unit or the body.

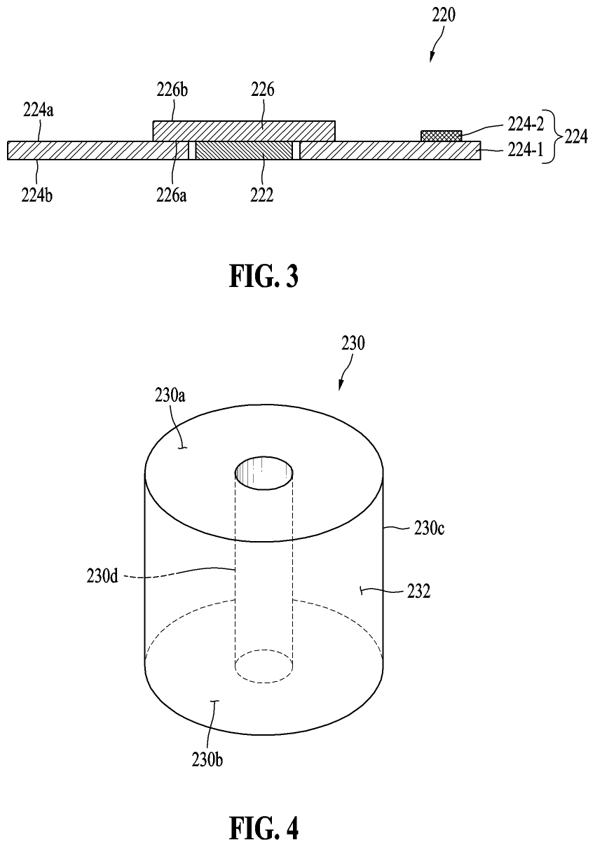

In an embodiment, the aerosol generating module 220 may include an ultrasonic vibrator 222, a surface acoustic wave vibrator 224, and a transfer element 226. The aerosol generating module 220 according to an embodiment is described in detail below with reference to FIG. 3.

In an embodiment, the cartridge 230 may be disposed in the housing 210 and may store an aerosol forming substrate (i.e., aerosol generating material). The aerosol forming substrate may be stored in the cartridge 230 in at least one of a gaseous phase, a liquid phase, or a solid phase. Desirably, the aerosol forming substrate may be stored in the cartridge 230 in the liquid phase. The aerosol forming substrate in the liquid phase may be, for example, a liquid including a tobacco-containing material that includes a volatile tobacco flavor component, or may be a liquid including a non-tobacco material. The aerosol forming substrate in the liquid phase may include, for example, water, a solvent, ethanol, a plant extract, a fragrance, a flavoring agent, or a vitamin mixture. The fragrance may include, for example, menthol, peppermint, spearmint oil, various fruit-flavored ingredients, and the like, but is not limited thereto. The flavoring agent may include ingredients that provide a user with a variety of flavors or scents. The vitamin mixture may be a mixture of at least one of vitamin A, vitamin B, vitamin C, or vitamin E, but is not limited thereto. The aerosol forming substrate in the liquid phase may also include an aerosol former such as glycerin and propylene glycol.

The cartridge 230 according to an embodiment is described in detail below with reference to FIG. 4.

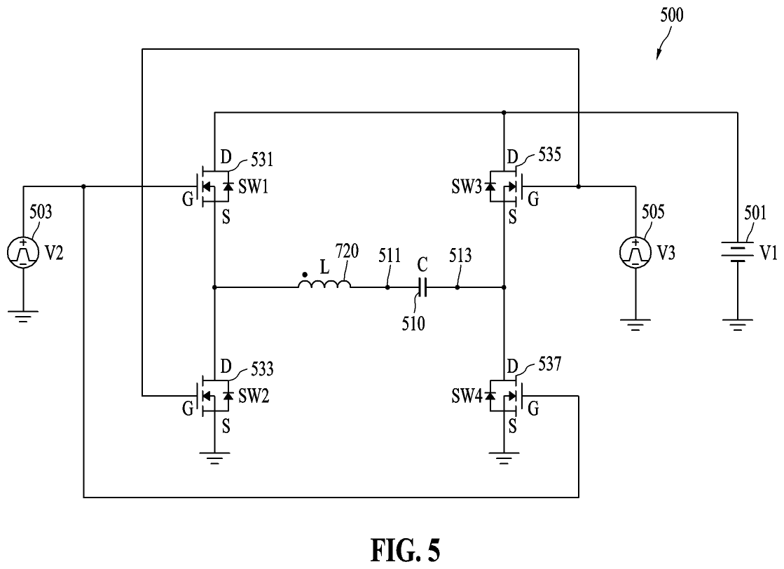

In an embodiment, when the ultrasonic vibrator 222 is electrically connected to the driving circuit 235, the driving circuit 235 may supply power to the ultrasonic vibrator 222. For example, a magnitude of the power supplied to the ultrasonic vibrator 222 may be controlled by the controller 240. A vibration frequency, or the like, of the ultrasonic vibrator 222 may be controlled depending on the magnitude of the power. The driving circuit 235 according to an embodiment is described in detail below with reference to FIG. 5.

In an embodiment, the controller 240 may include at least one processor. The processor may be implemented as an array of a plurality of logic gates, or may be implemented as a combination of a general-purpose microprocessor and a memory in which a program executable in the microprocessor is stored. The controller 240, included in the aerosol generating device 200 according to an embodiment, may control whether the ultrasonic vibrator 222 and the surface acoustic wave vibrator 224 of the aerosol generating module 220 vibrate and the vibration frequencies of the ultrasonic vibrator 222 and the surface acoustic wave vibrator 224. The controller 240 according to an embodiment is described in more detail below.

In an embodiment, the mouthpiece 250 is a portion that touches a mouth of the user, and an aerosol may be transferred to the user through an aerosol flow path included in the mouthpiece 250. In an embodiment, the mouthpiece 250 may be disposed at an end of the housing 210, and desirably, the mouthpiece 250 may be disposed to touch an end surface of the housing 210.

In an embodiment, the battery 260 (e.g., the battery 140 of FIG. 1) may supply power used to operate the aerosol generating device 200. For example, the battery 260 may supply power such that the ultrasonic vibrator 222 and the surface acoustic wave vibrator 224 of the aerosol generating module 220 may vibrate, and the battery 260 may supply power required for the controller 240 to operate. In addition, the battery 260 may supply power required to operate a display, a sensor, a motor, or the like installed in the aerosol generating device 200.

In an embodiment, the auxiliary elements 270 may include an elastic body 272, an electrode pin 274, and a wire 276. The auxiliary elements 270 according to an embodiment may include other additional units for smoothly operating the aerosol generating device 200 in addition to the above-described module and/or units. The elastic body 272 according to an embodiment may be disposed adjacent to the aerosol generating module 220 and compressed to apply pressure to the aerosol generating module 220 such that the aerosol forming substrate is smoothly transferred to the aerosol generating module 220 from the cartridge 230. As a distance between the transfer element 226 and the cartridge 230 of the aerosol generating module 220 is shortened by the compression of the elastic body 272, the aerosol forming substrate stored in the cartridge 230 in at least one of the gaseous phase, the liquid phase, or the solid phase may be efficiently transferred to the aerosol generating module 220. The electrode pin 274 and the wire 276 according to an embodiment may connect the controller 240 and the battery 260 to the aerosol generating module 220 such that the battery 260 transfers power to the aerosol generating module 220 and the controller 240 controls the aerosol generating module 220.

The aerosol generating module 220 controlled by the controller 240 is described below. In an embodiment, the controller 240 may control the aerosol generating device 200 such that the aerosol generating device 200 operates in one of at least two modes.

A first mode according to an embodiment may correspond to a mode in which the ultrasonic vibrator 222 and the surface acoustic wave vibrator 224 simultaneously vibrate. In the first mode, the ultrasonic vibrator 222 and the surface acoustic wave vibrator 224 may vibrate at different vibration frequencies and with different vibration periods, thereby acting as a main-vibration member and a sub-vibration member. When the ultrasonic vibrator 222 is the main-vibration member, the surface acoustic wave vibrator 224 is the sub-vibration member. When the surface acoustic wave vibrator 224 is the main-vibration member, the ultrasonic vibrator 222 is the sub-vibration member. When an aerosol is generated by the main-vibration member, the sub-vibration member may further increase an amount of the generated aerosol.

A second mode according to an embodiment may be a mode in which one of the ultrasonic vibrator 222 and the surface acoustic wave vibrator 224 vibrates first to preheat the aerosol forming substrate of the transfer element 226, and the other one of the ultrasonic vibrator 222 and the surface acoustic wave vibrator 224 vibrates to generate an aerosol. When the aerosol forming substrate is in the liquid phase, viscosity of the aerosol forming substrate may generally be high. It is desirable that a predetermined level of heat is applied to preheat the aerosol forming substrate such that the aerosol forming substrate is more smoothly aerosolized. Accordingly, one of the ultrasonic vibrator 222 and the surface acoustic wave vibrator 224 may vibrate to preheat the aerosol forming substrate included in the transfer element 226, and then the other one may vibrate to generate a larger amount of aerosol. In particular, when the aerosol forming substrate is to be preheated above a predetermined temperature (e.g., the Curie temperature) by vibration of the ultrasonic vibrator 222, components included in the ultrasonic vibrator 222 may be damaged, resulting in damage to the device. In this regard, the device may have better durability when the preheating is performed by the surface acoustic wave vibrator 224 and an aerosol is generated by the ultrasonic vibrator 222.

The controller 240 according to an embodiment may enable the aerosol generating device 200 to operate in various modes in addition to the above-described first and second modes.

FIG. 3 is a cross-sectional view of an aerosol generating module according to an example.

Referring to FIG. 3, the transfer element 226 included in the aerosol generating module 220 according to an embodiment may include a first surface 226a facing or disposed adjacent to the ultrasonic vibrator 222 and/or the surface acoustic wave vibrator 224, and a second surface 226b disposed opposite to the first surface 226a. The first surface 226a of the transfer element 226 according to an embodiment may be disposed to the ultrasonic vibrator 222 and/or the surface acoustic wave vibrator 224. Desirably, a partial region of the first surface 226a may be adjacent to the ultrasonic vibrator 222, and another partial region of the first surface 226a may be adjacent to the surface acoustic wave vibrator 224. As such, efficiency in aerosol generation may be improved by an interaction between the ultrasonic vibrator 222 and the surface acoustic wave vibrator 224. In the aerosol generating module 220 according to an embodiment, frictional heat may be generated by a vibration of at least one of the ultrasonic vibrator 222 and the surface acoustic wave vibrator 224, and some electrical energy may be converted into thermal energy in a process of converting electrical energy into mechanical energy through a piezoelectric body and/or a piezoelectric substrate 224-1. The heat and thermal energy may heat the aerosol forming substrate. As the temperature of the aerosol forming substrate increases, the viscosity of the aerosol forming substrate decreases, and accordingly, an aerosol may be more smoothly generated by the ultrasonic vibrator 222 and the surface acoustic vibrator 224.

The ultrasonic vibrator 222 according to an embodiment may include a piezoelectric body. The piezoelectric body according to an embodiment may be a conversion element that may convert electrical energy into mechanical energy and may generate an ultrasonic wave under the control of a controller (e.g., the controller 110 of FIG. 1). In an embodiment, when alternating current power is applied to a piezoelectric body that has undergone polarization processing, the piezoelectric body may repeatedly expand and contract. Accordingly, the ultrasonic vibrator 222 may vibrate at a characteristic frequency. In an embodiment, the ultrasonic vibrator 222 may further include a diaphragm (not shown) in contact with the piezoelectric body. The diaphragm in contact with the piezoelectric body may vibrate at the characteristic frequency together with the piezoelectric body due to the expansion and contraction of the piezoelectric body. One of ordinary skill in the art may obviously understand the principle of a piezoelectric vibration element, so any detailed description related thereto is omitted.

The ultrasonic vibrator according to an embodiment may include a piezoelectric transducer and a mesh plate. The piezoelectric transducer may be a conversion element that may convert electrical energy into mechanical energy and may generate an ultrasonic wave under the control of the controller (e.g., the controller 110 of FIG. 1). The mesh plate according to an embodiment may touch the aerosol forming substrate and atomize (aerosolize) the aerosol forming substrate. A vibration generated by the piezoelectric transducer may produce a pressure wave on the aerosol forming substrate, and the pressure wave may atomize the aerosol forming substrate by pushing the substrate into the gaps of the mesh plate.

The surface acoustic wave vibrator 224 according to an embodiment may include the piezoelectric substrate 224-1 and a transducer 224-2. The transducer 224-2 may include a first electrode and a second electrode. Each of the first electrode and the second electrode according to an embodiment may include two or more fingers. A piezoelectric substrate generated between the fingers may be deformed by being stretched and compressed due to a voltage applied to the individual fingers of the electrodes of the transducer 224-2. Accordingly, the piezoelectric substrate 224-1 may vibrate. A distance between the fingers of the electrodes according to an embodiment may correspond to a wavelength of a mechanical wave. The mechanical wave may generally have a nanometer-scale amplitude and may be propagated along a surface of the piezoelectric substrate 224-1. An aerosol may be generated by a surface acoustic wave generated by the surface acoustic wave vibrator 224 according to an embodiment.

In an embodiment, a commonly known surface acoustic wave (SAW) sensor chip may be used as the surface acoustic wave vibrator 224. The SAW sensor chip according to an embodiment may include at least one interdigital transducer including an electrode typically disposed on the piezoelectric substrate 224-1.

The transfer element 226 according to an embodiment may include the first surface 226a and the second surface 226b. A partial region of the first surface 226a of the transfer element 226 may be adjacent to the ultrasonic vibrator 222, and another partial region of the first surface 226a may be adjacent to the surface acoustic wave vibrator 224. For example, the first surface 226a of the transfer element 226 may include a first region Z1 and a second region Z2. In an embodiment, the first region Z1 of the first surface 226a of the transfer element 226 may be a region overlapping the ultrasonic vibrator 222. The second region Z2 of the first surface 226a of the transfer element 226 may be a region overlapping the surface acoustic wave vibrator 224. According to embodiments, areas of the first region Z1 and the second region Z2 may vary depending on the sizes of the ultrasonic vibrator 222 and the surface acoustic wave vibrator 224.

The transfer element 226 according to an embodiment may be a capillary tube element (e.g., a paper strip or a wick) for delivering the aerosol forming substrate from the cartridge, but embodiments are not limited thereto.

FIG. 4 is a schematic view of a cartridge according to an example.

The cartridge 230 according to an embodiment may include a first end wall 230a, a second end wall 230b disposed opposite to the first end wall 230a, and an outer wall 230c and an inner wall 230d connecting the first end wall 230a and the second end wall 230b. The first end wall 230a, the second end wall 230b, the outer wall 230c, and the inner wall 230d may form a storage space 232 for storing an aerosol forming substrate.

In this case, the cartridge 230 may include a through-hole that penetrates the first end wall 230a and the second end wall 230b. As such, an aerosol formed from an upper portion (e.g., the second surface 226b of the transfer element 226 of FIG. 3) of the transfer element 226 may travel through the through-hole. That is, the cartridge 230 according to an embodiment may include an airflow path (e.g., the airflow path P of FIG. 2) penetrating the first end wall 230a and the second end wall 230b and enclosed by the inner wall 230d, and the aerosol may be transferred to the mouthpiece 250 through the airflow path P and reach a mouth of a user.

FIG. 5 illustrates a driving circuit according to an embodiment.

A driving circuit 500 according to an embodiment may be included in a body of the aerosol generating device and may supply power to a vibrator 510 (e.g., the ultrasonic vibrator 222 of FIG. 3) included in a cartridge unit. The driving circuit 500 may include a first electrical contact 511 connectable to a first end of the vibrator 510, a second electrical contact 513 connectable to a second end of the vibrator 510, an inductor 520 (e.g., a coil) of which a first end is connected to the first electrical contact 511, a first switch SW1 531 having a source terminal connected to a second end of the inductor 520, a second switch SW2 533 having a drain terminal connected to the second end of the inductor 520 and having a source terminal connected to a ground, a third switch SW3 535 having a source terminal connected to the second electrical contact 513, a fourth switch 537 having a drain terminal connected to the second electrical contact 513 and having a source terminal connected to a ground, a first power supply 501 that provides a voltage to a drain terminal of the first switch 531 and a drain terminal of the third switch 535, a second power supply V2 503 that provides a voltage to a gate terminal of the first switch 531 and a gate terminal of the fourth switch 537, and a third power supply V3 505 that provides a voltage to a gate terminal of the second switch 533 and a gate terminal of the third switch 535. For example, each of the first switch 531, the second switch 533, the third switch 535, and the fourth switch 537 may be a switch based on a field effect transistor (FET). Here, when two elements are “connectable,” it refers to a configuration where the elements get connected to each other when a detachable part (e.g., a cartridge unit) of the aerosol generating device including one element is coupled to another detachable part (i.e., a body) of the aerosol generating device including the other element.

According to an embodiment, the vibrator 510 may be included in a cartridge unit. When the cartridge unit is mechanically coupled to a body, the vibrator 510 may be electrically connected to the first electrical contact 511 and the second electrical contact 513 of the driving circuit 500 by the coupling. When the first electrical contact 511 and the second electrical contact 513 are connected through the vibrator 510, the controller 240 may recognize that the vibrator 510 is coupled and may supply power to the vibrator 510 through the driving circuit 500.

The first power supply 501 according to an embodiment may provide a direct current (DC) voltage to the drain terminal of the first switch 531 and the drain terminal of the third switch 535. For example, the direct current voltage may be less than or equal to 15 volts (V) (e.g., 10 V), but embodiments are not limited thereto.

The second power supply 503 according to an embodiment may provide a first alternating current (AC) voltage to the gate terminal of the first switch 531 and the gate terminal of the fourth switch 537, and the third power supply 505 may provide a second alternating current voltage to the gate terminal of the second switch 533 and the gate terminal of the third switch 535. For example, a peak value of the first alternating current voltage and a peak value of the second alternating current voltage may be less than or equal to 4 V, but embodiments are not limited thereto.

The second power supply 503 and the third power 505 supply according to an embodiment may operate alternately. That is, the second power supply 503 and the third power supply 505 may not operate simultaneously. A voltage between the first end and the second end of the vibrator 510 provided by the driving circuit 500 (i.e., the voltage between the first electrical contact 511 and the second electrical contact 513 when the vibrator 510 is electrically connected to the driving circuit) may be greater than or equal to 100 V, but embodiments are not limited thereto.

When the driving circuit 500 is used, it may be possible to apply a high voltage to generate a vibration of the vibrator 510 even at a voltage (e.g., 10 V) lower than a voltage (e.g., 17 V) applied to a switch of a driving circuit in a form of a boost converter.

Since a voltage applied to a switch of the driving circuit 500 is a voltage (e.g., 10 V) directly applied to a drain of the switch, there is no need for a switch capable of handling a high voltage. Accordingly, a switch with a low Rds(on) resistance may be applied to the driving circuit 500, and issues such as component overheating may be reduced.

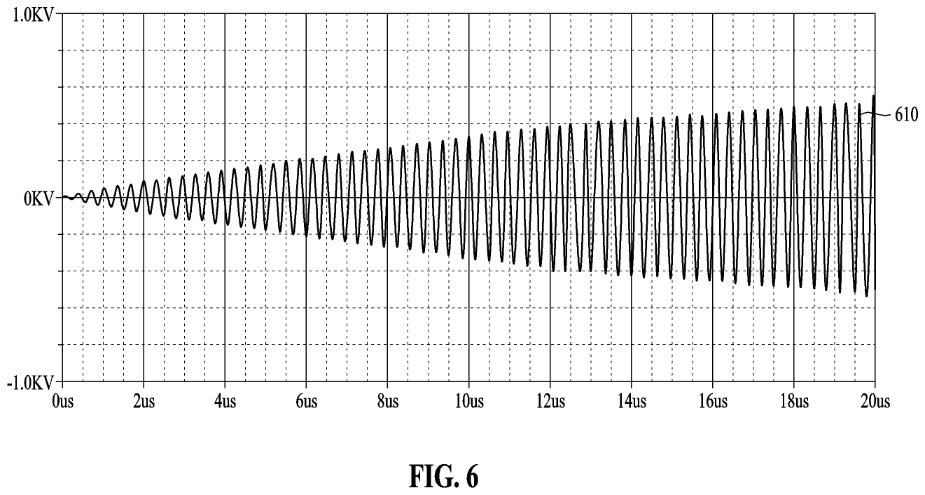

FIG. 6 illustrates a voltage applied to a vibrator through a driving circuit according to an example.

According to an embodiment, a waveform 610 of a voltage applied through the driving circuit 500 to the first end and the second end of the vibrator 510 is illustrated in FIG. 6. For example, the first power supply 501 of the driving circuit 500 may provide a direct current voltage of 10 V, and alternating current voltages of the second power supply 503 and the third power supply 505 may be provided alternately. For this experiment, the alternating current voltages of the second power supply 503 and the third power supply 505 are set to have a peak of 3.3 V, a delay time (TD) of 0, a rise time (TR) of 10 nanoseconds (ns), a fall time (TF) of 10 ns, a pulse width (PW) of 0.16 microsecond (μs), and a period (PER) of 0.32 μs.

Under the above-mentioned conditions, a voltage across the vibrator 510 may reach 500 V at about 20 μs. A magnitude of the voltage applied to the vibrator 510 may be controlled by adjusting operating frequencies of the second power supply 503 and the third power supply 505 and voltages and currents applied to the switches.

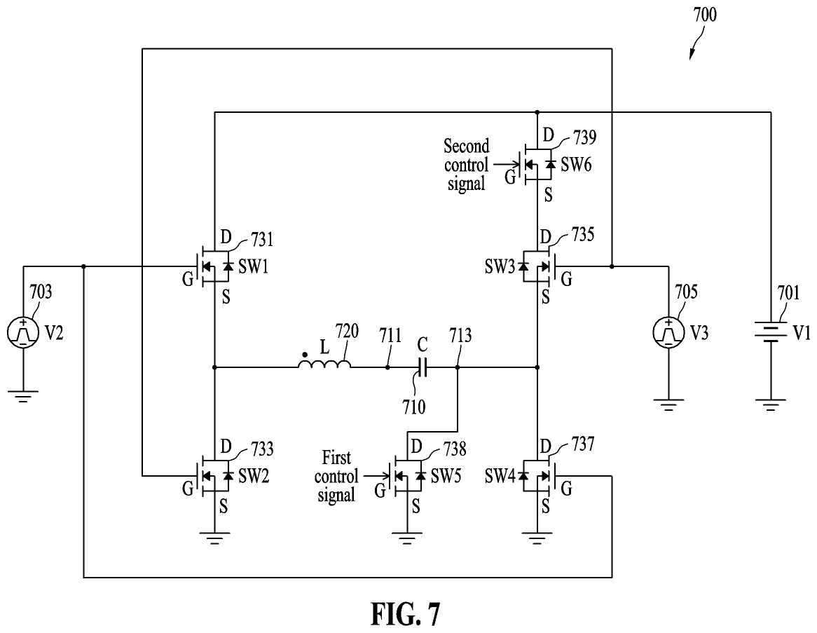

FIG. 7 illustrates a driving circuit for switching between a full bridge mode and a half bridge mode according to an embodiment.

According to an embodiment, when compared with the driving circuit 500 described with reference to FIG. 5, a driving circuit 700 may further include a fifth switch 738 connected to a second electrical contact 713 and a sixth switch 739 positioned between a drain terminal of a third switch 735 and a first power supply 701. A source terminal of the sixth switch 739 is connected to the drain terminal of the third switch 735, and a drain terminal of the sixth switch 739 is connected to the first power supply 701. For example, a first control signal provided to a gate terminal of the fifth switch 738 and a second control signal provided to a gate terminal of the sixth switch 739 may be different from each other, and the first control signal and the second control signal may be provided by the controller 240.

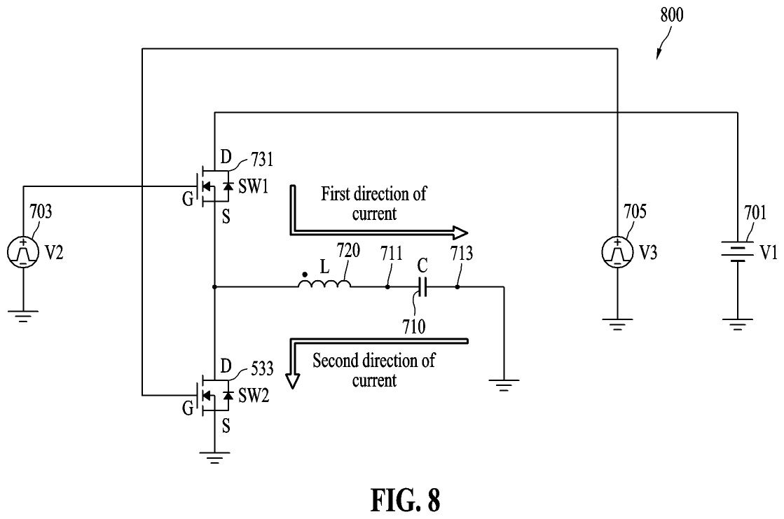

FIG. 8 illustrates an equivalent circuit of a driving circuit that operates in a half bridge mode according to an embodiment.

According to an embodiment, when a first control signal is LOW and a second control signal is HIGH, the driving circuit 700 may operate in a full bridge mode. Conversely, when the first control signal is HIGH and the second control signal is LOW, the driving circuit 700 may operate in a half bridge mode. FIG. 8 may illustrate an equivalent circuit 800 of the driving circuit 700 that operates in the half bridge mode.

According to an embodiment, when the second power supply 703 and the third power supply 705 operate alternately, a direction of a current flowing through the vibrator 710 may also change alternately.

When compared with the full bridge mode, in the half bridge mode, a maximum voltage applied to the vibrator 710 may be reduced, and the total power consumed by the driving circuit 700 may also be reduced. In this regard, when the aerosol generating device 200 operates in a mode in which a relatively smaller amount of aerosol is generated, the half bridge mode may be used. For example, in the half bridge mode, the voltage the first electrical contact 711 and the second electrical contact 713 (i.e., the voltage across the vibrator 710) may be greater than or equal to 50 V.

The methods according to the embodiments may be recorded in non-transitory computer-readable media including program instructions to implement various operations of the embodiments. The media may also include, alone or in combination with the program instructions, data files, data structures, and the like. The program instructions recorded on the media may be those specially designed and constructed for the purposes of embodiments, or they may be of the kind well-known and available to one of ordinary skill in the computer software arts. Examples of non-transitory computer-readable media include magnetic media such as hard disks, floppy disks, and magnetic tape; optical media such as CD-ROM discs or DVDs; magneto-optical media such as floptical disks; and hardware devices that are specially configured to store and perform program instructions, such as read-only memory (ROM), RAM, flash memory, and the like. Examples of program instructions include both machine code, such as produced by a compiler, and files containing higher-level code that may be executed by the computer using an interpreter. The above-described hardware devices may be configured to act as one or more software modules in order to perform the operations of the embodiments, or vice versa.

The software may include a computer program, a piece of code, an instruction, or one or more combinations thereof, to independently or collectively instruct or configure the processing device to operate as desired. Software and/or data may be embodied permanently or temporarily in any type of machine, component, physical or virtual equipment, computer storage medium or device, or in a propagated signal wave capable of providing instructions or data to or being interpreted by the processing device. The software may also be distributed over network-coupled computer systems so that the software may be stored and executed in a distributed fashion. The software and data may be stored by one or more non-transitory computer-readable recording mediums.

Although the embodiments have been described with reference to the limited drawings, one of ordinary skill in the art may apply various technical modifications and variations based thereon. For example, suitable results may be achieved if the described techniques are performed in a different order and/or if components in a described system, architecture, device, or circuit are combined in a different manner or replaced or supplemented by other components or their equivalents.

Therefore, other implementations, other embodiments, and equivalents to the claims are also within the scope of the following claims.

1. A driving circuit for operating a vibrator, comprising:
a first electrical contact connectable to a first end of the vibrator;
a second electrical contact connectable to a second end of the vibrator;
an inductor having a first end connected to the first electrical contact;
a first switch having a source terminal connected to a second end of the inductor;
a second switch having a drain terminal connected to the second end of the inductor and having a source terminal connected to a ground;
a third switch having a source terminal connected to the second electrical contact;
a fourth switch having a drain terminal connected to the second electrical contact and having a source terminal connected to a ground;
a first power supply configured to provide a voltage to a drain terminal of the first switch and a drain terminal of the third switch;
a second power supply configured to provide a voltage to a gate terminal of the first switch and a gate terminal of the fourth switch; and
a third power supply configured to provide a voltage to a gate terminal of the second switch and a gate terminal of the third switch.

2. The driving circuit of claim 1, wherein the first power supply is configured to provide a direct current voltage to the drain terminal of the first switch and the drain terminal of the third switch.

3. The driving circuit of claim 1, wherein a direct current voltage provided by the first power supply is less than or equal to 15 volts (V).

4. The driving circuit of claim 1, wherein
the second power supply provides a first alternating current voltage to the gate terminal of the first switch and the gate terminal of the fourth switch, and
the third power supply provides a second alternating current voltage to the gate terminal of the second switch and the gate terminal of the third switch.

5. The driving circuit of claim 4, wherein a peak value of the first alternating current voltage and a peak value of the second alternating current voltage are less than or equal to 4 V.

6. The driving circuit of claim 4, wherein the second power supply and the third power supply operate alternately.

7. The driving circuit of claim 5, wherein a voltage between the first electrical contact and the second electrical contact is greater than or equal to 100 V.

8. The driving circuit of claim 1, further comprising:
a fifth switch connected to the second electrical contact; and
a sixth switch positioned between the drain terminal of the third switch and the first power supply,
wherein a source terminal of the sixth switch is connected to the drain terminal of the third switch, and a drain terminal of the sixth switch is connected to the first power supply, and
wherein a first control signal provided to a gate terminal of the fifth switch and a second control signal provided to a gate terminal of the sixth switch are different from each other.

9. The driving circuit of claim 8, wherein a voltage between the first electrical contact and the second electrical contact is greater than or equal to 50 V.

10. An aerosol generating device including the driving circuit of claim 1.

11. An aerosol generating device comprising:
a cartridge unit comprising a vibrator configured to generate an aerosol by vibrating an aerosol generating material; and
a body detachably coupled to the cartridge unit and comprising a driving circuit configured to operate the vibrator,
wherein the driving circuit comprises:
a first electrical contact connectable to a first end of the vibrator;
a second electrical contact connectable to a second end of the vibrator;
an inductor having a first end connected to the first electrical contact;
a first switch having a source terminal connected to a second end of the inductor;
a second switch having a drain terminal connected to the second end of the inductor and having a source terminal connected to a ground;
a third switch having a source terminal connected to the second electrical contact;
a fourth switch having a drain terminal connected to the second electrical contact and having a source terminal connected to a ground;
a first power supply configured to provide a voltage to a drain terminal of the first switch and a drain terminal of the third switch;
a second power supply configured to provide a voltage to a gate terminal of the first switch and a gate terminal of the fourth switch; and
a third power supply configured to provide a voltage to a gate terminal of the second switch and a gate terminal of the third switch, and
wherein the vibrator is connected to the driving circuit when the body is coupled to the cartridge unit.
